(19) United States
(12) Patent Application Publication
(10) Pub. No.: US 2025/0285663 A1
(43) Pub. Date: Sep. 11, 2025

(54) MEMORY CIRCUITS WITH REGISTER CIRCUTIS AND METHODS FOR OPERATING THE SAME

(71) Applicant: Taiwan Semiconductor Manufacturing Company, Ltd., Hsinchu (TW)

(72) Inventors: Meng-Sheng Chang, Chu-bei City (TW); Shao-Ting Wu, Xinfeng Township (TW); Shao-Yu Chou, Xinfeng Township (TW); Yih Wang, Xinfeng Township (TW)

(73) Assignee: Taiwan Semiconductor Manufacturing Company, Ltd., Hsinchu (TW)

(21) Appl. No.: 18/790,547

(22) Filed: Jul. 31, 2024

Related U.S. Application Data
(60) Provisional application No. 63/562,907, filed on Mar. 8, 2024.
(60) Provisional application No. 63/572,512, filed on Apr. 1, 2024.

(51) Int. Cl. G11C 7/10; G11C 7/06; H03K 3/037; H03K 19/20

(52) U.S. Cl. CPC G11C 7/1069; G11C 7/06; H03K 3/037; H03K 19/20

(57) ABSTRACT

A memory circuit includes a memory array comprising a plurality of first memory cells and a plurality of second memory cells, each of the plurality of first memory cells configured to store a data bit and each of the plurality of second memory cells configured to store a repair bit; a plurality of register circuits; and a compare circuit coupled to the plurality of register circuits. Each of the plurality of register circuits is configured to receive the repair bit from a corresponding one of the plurality of second memory cells; transfer the received repair bit to the compare circuit when the memory circuit is configured in a first operation mode; and latch the received repair bit in the register circuit when the memory circuit is configured in a second operation mode.

### CROSS-REFERENCE TO RELATED APPLICATION

This application claims priority to and the benefit of U.S. Provisional Application No. 63/562,907, filed Mar. 8, 2024, and U.S. Provisional Application No. 63/572,512, filed Apr. 1, 2024, each of which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example memory circuit including a repair circuit, in accordance with some embodiments.

FIG. 2 illustrates a circuit diagram of a portion of the memory circuit of FIG. 1, in accordance with some embodiments.

FIG. 3 illustrates a circuit diagram of the repair circuit of FIG. 1, in accordance with some embodiments.

FIG. 4 illustrates a schematic diagram of a portion of a compare circuit of the repair circuit of FIG. 3, in accordance with some embodiments.

FIG. 5 illustrates a schematic diagram of a portion of a multiplexer of the repair circuit of FIG. 3, in accordance with some embodiments.

FIG. 6 illustrates waveforms of various signals when operating the memory circuit of FIG. 1, in accordance with some embodiments.

FIG. 7 illustrates another implementation of the memory circuit of FIG. 1, in accordance with some embodiments.

FIG. 8 illustrates an example layout that can be utilized to form the memory circuit of FIG. 1, in accordance with some embodiments.

FIG. 9 illustrates a flow chart of an example method for operating a memory circuit that includes a repair circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with the scaling trend to integrate an increasing number of components on a given area, integrated circuits have become key components of many consumer and commercial electronic products, often replacing discrete components and enhancing functionality. The semiconductor processing technologies that produce these integrated circuits have advanced to the point wherein complete systems, including memories, can be reduced to a single integrated circuit, which can be an application specific integrated (ASIC) device or a system-on-a-chip (SOC) device.

Embedded random access memory (RAM) is among the most widely used cores in the current implementations of integrated circuits. A variety of RAM types have been proposed or adopted such as, for example, one-time-programmable (OTP) memory cells, magnetic random access memory (MRAM) cells, resistive random access memory (RRAM) cells, static random access memory (SRAM) cells, phase change random access memory (PCRAM) cells, or the like. Embedded RAM gives rise to problems during chip manufacturing. For example, because an embedded RAM occupies a significant portion of a chip's area, the probability that a defect lies within the RAM is relatively high. The RAM thus becomes a controlling factor in chip yield. In general, the embedding of RAM not only makes its own testing difficult, but also impairs testability of all other functions on chip, such as the core logic.

The present disclosure provides various embodiments of a memory circuit including a memory array and a repair circuit. The memory array can include a number of main memory cells that are each configured to store a data bit, and a number of secondary (or redundant) memory cells that are each configured to store a repair bit. In various embodiments of the present disclosure, the repair circuit can include a number of register circuits that are configured to load, retrieve, or otherwise receive the repair bits from the memory array. Based on switching to an operation mode of the memory circuit through a number of control signals, each of the register circuits can selectively transfer the received repair bits to a later stage of circuits or latch the received repair bits within the register circuit. For example, during a repair read mode, a number of the repair bits can be transferred to a compare circuit formed in a later stage. The compare circuit can further compare the repair bits with an address signal indicating a location of the main memory cell, such as to determine whether to replace (e.g., repair) the data bit stored by the main memory cell. In another example, during a power down mode, the (e.g., previously) received repair bits can be latched within the register circuits, even without power supplied. This can provide a variety of advantages in terms of power consumption. In the existing technologies, such repair bits are generally erased or gone right after the supply power is removed. By contrast, through the disclosed repair circuit which includes a number of register circuits that function differently according to the operation mode of the memory circuit, the repair bits can be kept in the repair circuits even without power supplied. As such, when the disclosed memory circuit transitions back from a power down mode, the memory circuit no longer needs to transition to another repair read mode and can directly transition to a normal read mode, which can advantageously save power consumption of the memory circuit.

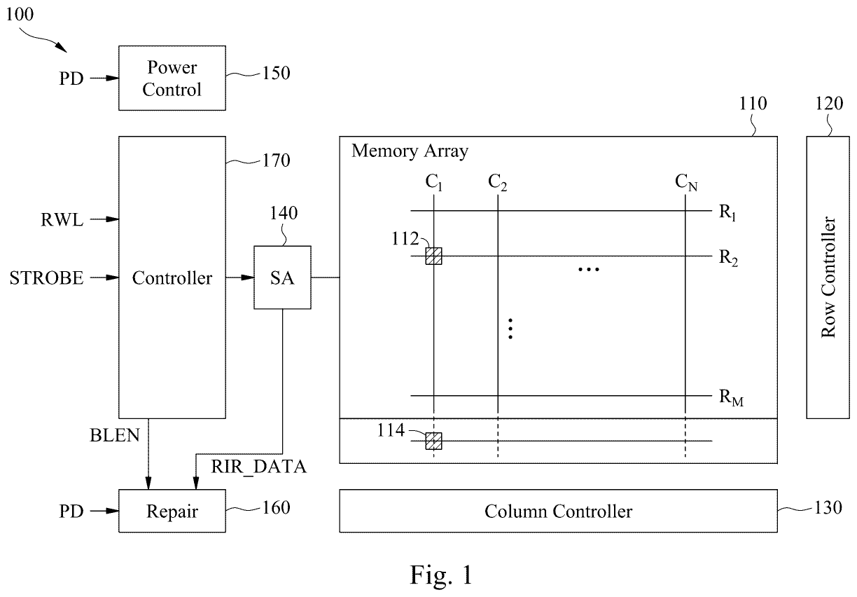

FIG. 1 illustrates a block diagram of a memory circuit 100, in accordance with various embodiments. In the illustrated embodiment of FIG. 1, the memory circuit 100 includes a memory array 110, a row controller 120 (e.g., including a number of decoders), a column controller 130 (e.g., including a number of decoders), an input/output (I/O) circuit 140 (e.g., including a number of sensing circuits), a power control circuit 150, a repair circuit 160, and a control circuit 170. Although, in the illustrated embodiment of FIG. 1, each component of the memory circuit 100 is shown as a separate block for the purpose of clear illustration, in some other embodiments, some or all of the components shown in FIG. 1 may be integrated together. Further, the illustrated example of FIG. 1 is merely an example, and thus, it should be understood that the memory circuit 100 can include any of various other or same components while remaining within the scope of the present disclosure.

The memory array 110 is a hardware component that is configured to store data bits or repair bits. In some embodiments, the memory array 110 is embodied as a semiconductor memory device including a number of memory cells. Although one memory array is shown, it should be appreciated that the memory circuit 100 can include a plural number of memory arrays, each of which may sometimes be referred to as a memory bank. In the illustrative example of FIG. 1, the memory array 110 includes a plurality of main or first memory cells (or otherwise storage units) 112. The memory array 110 includes a number of rows R₁, R₂, R₃ . . . . RM, each extending in a first direction and a number of columns C₁, C₂, C₃ . . . . CN, each extending in a second direction. Each of the rows/columns may include one or more conductive structures. In some embodiments, each main memory cell 112 is arranged in the intersection of a corresponding row and a corresponding column and can be operated according to voltages or currents through the respective conductive structures of the column and row.

Further, in the example of FIG. 1, the memory array 110 can include one or more redundant or second memory cells (or otherwise storage units) 114 formed in redundant or spare columns or rows. The second memory cells 114 are generally configured for repairing failed first (main) memory cells 112. In some embodiments, such redundant rows or columns may be physically disposed on an edge or within an edge row/column of the memory array 110. In general, the number of redundant rows/columns depends on a size of the memory array 110 and also depends on the manufacturing processes used to make the memory array 110 and its size. Larger main memory array (with more rows and columns) may be associated with more redundant rows and columns to assist in cell repair. Additionally, if the processes used to manufacture the device have high yield, the number of redundant rows/columns could be lower. In contrast, if the processes have low yield, the number of redundant rows/columns needed would be higher.

In various embodiments of the present disclosure, the first (main) memory cell 112 is configured to store a data bit, and the second (redundant) memory cell 114 is configured to store a repair bit. A plural number of the repair bits (respectively stored by a plural number of the second memory cells 114) can collectively form a repair signal associated with a corresponding one of the first memory cells 112. In some embodiments, the plural repair bits of a repair signal can indicate a location of the corresponding first memory cell in the memory array (e.g., at the intersection of which column and which row), whether the plural number of the repair bits are still capable of repairing, and whether the corresponding first memory cell should be repaired as logic 0 or logic 1 which is sometimes referred to as a should-be-repaired (SBR) bit. As a non-limiting example where a repair signal has 16 repair bits, the 16 repair bits (or 16 second memory cells 114) can correspond to one first memory cell 112. Further, 1 of the 16 repair bits can indicate whether these 16 repair bits are still capable of repairing, 1 of the 16 repair bits can indicate whether the corresponding first memory cell 112 should be repaired as logic 0 or 1, and 14 of the 16 repair bits can indicate an address of the first memory cell 112 in the memory array 110 (sometimes referred to as repair address bits).

In one of various example embodiments of the present disclosure, each of the memory cells 112/114 may be implemented as an efuse cell. The efuse cell can include a fuse resistor and an access transistor connected in series. The access transistor can be coupled to (e.g., gated by) a corresponding WL. The access transistor can be turned on/off to enable/disable an access (e.g., program, read) to the corresponding fuse resistor. One end of the fuse resistor is connected to a BL, with the other end of the fuse resistor connected to one of the source/drain terminals of the access transistor. Upon being selected, the access transistor of the selected efuse cell is turned on by asserting (e.g., pulling up) the WL to allow a program or read path to be formed through its fuse resistor and itself. With a program or read voltage applied on the BL, a data/repair bit can be programmed into or read from the fuse resistor. However, it should be understood that each of the memory cells 112/114 can be implemented as any of various other RAM cells (e.g., an anti-fuse cell, an MRAM cell, an RRAM cell, a PCRAM cell, etc.), while remaining within the scope of the present disclosure.

The row controller 120 is a hardware component that can receive a row address of the memory array 110 and assert a conductive structure (e.g., a WL) at that row address. The column controller 130 is a hardware component that can receive a column address of the memory array 110 and assert one or more conductive structures (e.g., a BL) at that column address. The power control circuit 150 can receive a supply voltage (e.g., VDD) and, based on the supply voltage, provide one or more different operation voltages (e.g., VDDHD, VDDQ, etc.) to respectively drive the components of the memory circuit 100. For example, VDDHD may be configured for driving logic components of the memory circuit 100, and VDDQ may be configured for programming the memory cells of the memory circuit 100. Further, in some embodiments, the power control circuit 150 can receive a control signal (PD) with a logic state, e.g., logic 1, causing the memory circuit 100 to transition into a power down mode. The I/O circuit 140 is a hardware component that can access (e.g., read) each of the memory cells 112/114 asserted through the row controller 120 and column controller 130. In some embodiments, the I/O circuit 140 can include one or more sensing circuits configured to load the repair bit (e.g., read from the second memory cell 114) into the repair circuit 160 as “RIR_DATA.” The controller circuit 170 is a hardware component that can control the coupled components of the memory circuit 100. In some embodiments, the controller circuit 170 can receive a plural number of control signals (e.g., an RWL signal, a STROBE signal, etc.) to provide a BLEN signal to the repair circuit 160. Based on a logic state of the BLEN signal and/or a logic state of the PD signal, the repair circuit 160 can selectively forward the RIR_DATA to a circuit component in a later stage or latch the RIR DATA within the repair circuit 160. Detailed descriptions on operation of the memory circuit 100 (e.g., the repair circuit 160) will be provided below.

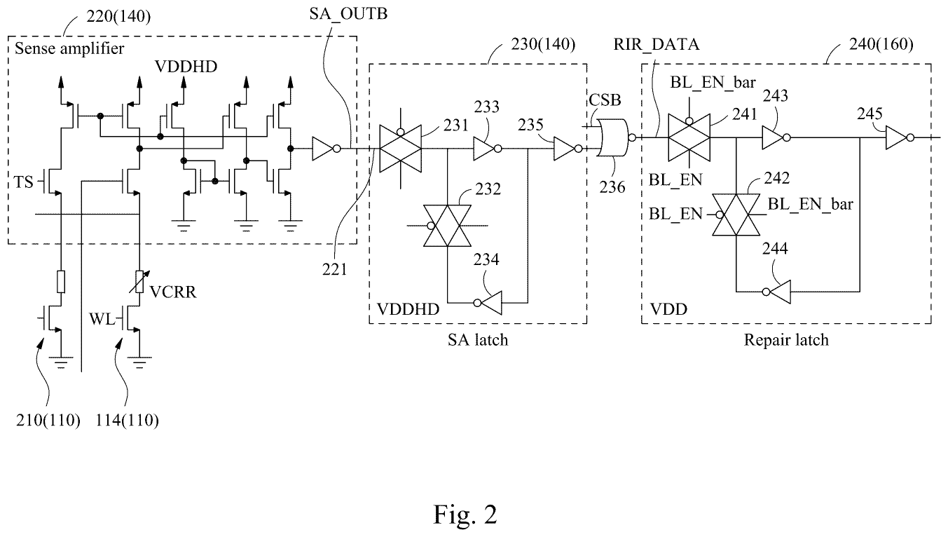

FIG. 2 illustrates an example circuit diagram of a portion of the memory circuit 100, in accordance with various embodiments. For example, one of the second memory cells 114 that stores a repair bit, a portion of the I/O circuit 140, and a portion of the repair circuit 160 are shown in the circuit diagram of FIG. 2. As shown, the memory array 110 includes one second memory cell 114 and one or more reference cells 210; the I/O circuit 140 includes a plural number of transistors that operatively serve as a sense amplifier 220, and includes a sense amplifier latch 230; and the repair circuit 160 includes a repair latch 240. It should be noted that the circuit diagram of FIG. 2 is merely provided as a non-limiting example to illustrate a portion of the memory circuit 100, and thus, the circuit diagram of FIG. 2 can include any suitable circuit implementations of other components of the memory circuit 100 while remaining within the scope of the present disclosure.

In some embodiments, the reference cells 210 can present two resistances representing a high reference resistance and a low reference resistance, respectively. These two resistances can be coupled in parallel with each other and commonly coupled to one side of a voltage comparator (shown as a part of the sense amplifier 220). The sense amplifier 220 may be powered by VDDHD (provided by the power control circuit 150). For example, the voltage comparator, which may be formed of a first p-type transistor and a second p-type transistor, can have a first side and a second side connected to the parallel reference cells 210 and the second memory cell 114, respectively. The second memory cell 114 shown in FIG. 2 can represent a selected one of the second memory cells 114 of the memory array. The reference cells 210 can serve as a current sink to the connected first p-type transistor. The second p-type transistor (on the other side of the voltage comparator) may be drained through the selected second memory cell 114, whose resistance is to be distinguished. When the voltage at the side of the reference cells 210 is lower than the voltage at the side of the selected second memory cell 114, the voltage comparator can be turned on and an output of the sense amplifier 220 can be outputted with a high resistance (i.e., a first logic state). When the voltage at the side of the reference cells 210 is higher than the voltage at the side of the selected second memory cell 114, the voltage comparator can be turned off and an output of the sense amplifier 220 can be outputted with a low resistance (i.e., a second logic state). Accordingly, a logic state of the repair bit stored in the second memory cell 114 can be distinguished and outputted as a signal 221.

The sense amplifier latch 230 can include a first transmission gate 231, a second transmission gate 232, a first inverter 233, a second inverter 234, and a third inverter 235. The sense amplifier latch 230 may be powered by VDDHD (provided by the power control circuit 150). In some embodiments, the transmission gates 231 and 232 may be alternately activated to pass along the received signal. As will be discussed below, the transmission gate 231 can be activated/deactivated based on a logic state of the STROBE signal, and the transmission gate 232 can be activated/deactivated based on the logic state of the STROBE signal. As such, when the transmission gate 231 is activated (with the transmission gate 232 deactivated), the signal 221 can be forwarded through the inverters 233, 235 to a later stage, e.g., NOR gate 236; and when the transmission gate 231 is deactivated (with the transmission gate 232 activated), the (e.g., previously loaded) signal 221 can be latched within the sense amplifier latch 230 (e.g., within the transmission gate 232 and the inverters 233, 234). In some embodiments, one of the inputs of the NOR gate 236 can receive another control signal (CSB), which may be kept at logic 0 except that the memory circuit 100 transitions to the power down mode (e.g., when the PD signal is at logic 1). The other input of the NOR gate 236 can receive the forwarded signal 221. Accordingly, the NOR gate 236 can output the RIR_DATA by NOR'ing the forwarded signal 221 and the CSB signal.

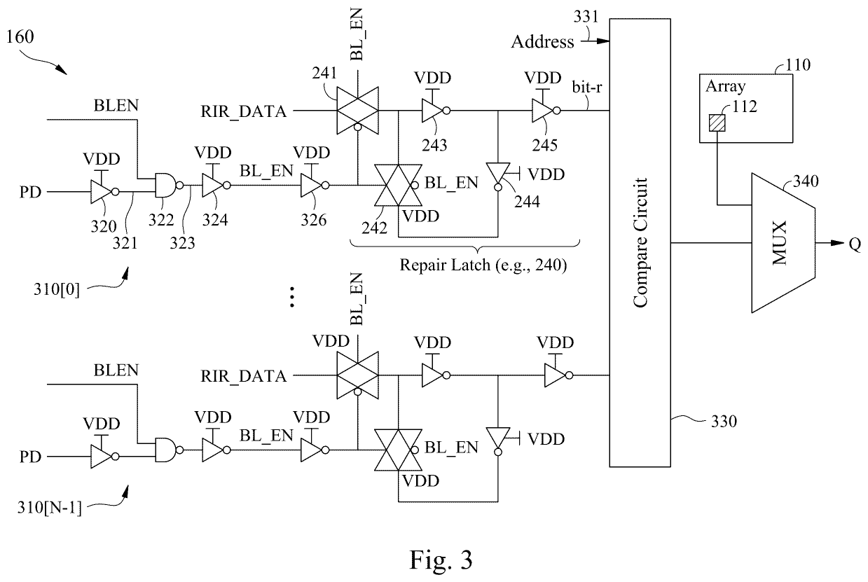

The repair latch 240 can include a first transmission gate 241, a second transmission gate 242, a first inverter 243, a second inverter 244, and a third inverter 245. The repair latch 240 may be powered by the provided supply voltage VDD. Different from the VDDHD driving the sense amplifier 220 and the sense amplifier latch 230 that may be removed when the memory circuit 100 transitioning to the power down mode, the VDD may remain supplied to the memory circuit 100. In some embodiments, the transmission gates 241 and 242 may be alternately activated to pass along the received signal. As will be discussed below, the transmission gate 241 can be activated/deactivated based on a logic state of another control signal (BL_EN), and the transmission gate 242 can be activated/deactivated based on the logic state of the BL EN signal. As such, when the transmission gate 241 is activated (with the transmission gate 244 deactivated), the RIR DATA can be forwarded through the inverters 243, 245 to a later stage, e.g., a compare circuit (which will be shown in FIG. 3); and when the transmission gate 241 is deactivated (with the transmission gate 244 activated), the (e.g., previously loaded) RIR_DATA can be latched within the repair latch 240 (e.g., within the transmission gate 242 and the inverters 243, 244). In some embodiments, depending on the operation mode of the memory circuit 100, the RIR DATA can be selectively outputted by the repair latch 240 as one of plural bits of a repair signal (e.g., a bit_r bit) or latched within the repair latch 240.

FIG. 3 illustrates a schematic diagram of the repair circuit 160, in accordance with various embodiments. For example, the repair circuit 160 includes a plural number of register circuits 310[0] . . . 310[N−1], where each of the register circuits includes the repair latch 240 (shown in FIG. 2) and other components (e.g., 320, 322, 324, and 326). It should be noted that the schematic diagram of FIG. 3 is merely provided as a non-limiting example, and thus, the schematic diagram of FIG. 3 can include any suitable circuit implementations of other components of the memory circuit 100 while remaining within the scope of the present disclosure.

In some embodiments, the repair circuit 160 can further include a compare circuit 330 coupled to the register circuits 310[0] to 310[N−1], and a multiplexer 340. As a non-limiting example, N is equal to 256. That is, the repair circuit 160 has 256 register circuits 310. In some examples, these 256 register circuits 310 can be divided into 16 groups, in which each of these 16 groups can have 16 bits and correspond to (e.g., be configured for repairing) one of the first memory cells 112. The 16 bits of each group can correspond to a repair signal (as described above) of the corresponding first memory cell 112.

Using the register circuit 310[0] as a representative example, the register circuit 310[0] has a first inverter 320, a NAND gate 322, a second inverter 324, and a fourth inverter 326. Similar to the repair latch, each of these components 320 to 326 is powered by the supply voltage VDD. Further, the inverter 320 can receive the PD signal and logically invert the PD signal as a signal 321; the NAND gate 322 can receive the signal 321 and the BLEN signal (provided by the controller circuit 170), and NAND the signal 321 and BLEN signal as a signal 323; the inverter 324 can logically invert the signal 323 as another control signal (BL_EN); and the inverter 326 can logically invert the BL_EN signal to control the transmission gates 241-242 of the repair latch, according to some embodiments. In some other embodiments, a resistor can be coupled to one of the inputs of the NAND gate 322 that receives the BLEN signal.

As will be discussed in further detail below, the register circuit (e.g., 310[0]) can switch between latching and forwarding the RIR_DATA, when the memory circuit 100 transitions to (or is configured in) the repair read mode; and the register circuit (e.g., 310[0]) can latch the RIR DATA, when the memory circuit 100 transitions to (or is configured in) the power down mode. Those different operation modes of the memory circuit 100 can be configured through at least the PD signal, RWL signal, and STROBE signal. Further, the BLEN signal can be provided with a logic state based on different logic states of the RWL signal and the STROBE signal.

For example, when the BLEN signal is provided at (or logically combined as) logic 1 and the memory circuit 100 is not configured in the power down mode (e.g., the PD signal=0) and configured in the repair read mode (e.g., the RWL signal=1), the register circuit can forward the RIR DATA. In another example, when the BLEN signal is provided at (or logically combined as) logic 0 and the memory circuit 100 is not configured in the power down mode (e.g., the PD signal=0) and configured in the repair read mode (e.g., the RWL signal=1), the register circuit can latch the RIR_DATA. In yet another example, when the memory circuit 100 is configured in the power down mode (e.g., the PD signal=1), the register circuit can latch the RIR_DATA regardless of a logic state of the BLEN signal.

In addition to receiving the bit_r bit from each of the register circuits 310[0] to 310[N−1], the compare circuit 330 can further receive an address signal 331 and compare the address signal 331 with the addresses indicated by some of the received bit_r bits. In some embodiments, the address signal 331 can represent a location of one of the to-be-repaired first memory cells 112 in the memory array 110, e.g., the intersection of which column and which row. In the above example where 256 register circuits 310 are coupled to the compare circuit 330, the compare circuit 330 can receive 16 groups of addresses, each of which has 14 repair address bits.

In response to having a match (e.g., the address signal 331 is the same as any of the 16 groups of 14 repair address bits that correspond to a location of one to-be-repaired first memory cell 112), the compare circuit 330 can provide a “HIT” signal with a logic state (e.g., logic 1) to the multiplexer 340. Still with the above example, the compare circuit 330 may provide a plural number (e.g., 16) of these HIT signals. In some embodiments, the 16 HIT signals provide 16 opportunities to match the to-be-repaired first memory cell 112. Alternatively stated, the 16 HIT signals indicate whether the location of the to-be-repaired first memory cell 112 match the 16 groups of repair address bits loaded from the second memory cells 114, respectively.

The multiplexer 340 can receive those (e.g., 16) HIT signals, each of which may have 1 bit. Further, the multiplexer 340 can receive at least some of the bit_r bits forwarded by the register circuits 310[0] to 310[N−1]. Still with the above example, the multiplexer 340 can receive at least 16 bit_r bits (out of the 16 groups) that indicate whether the corresponding first memory cell 112 should be repaired as logic 0 or logic 1. Each of the HIT signals can correspond to a respective one of 16 should-be-repaired bits. Accordingly, the multiplexer 340 can include 16 blocks, each of which is configured to receive a corresponding one of the 16 should-be-repaired logic 1 or 0 and a corresponding one of the 16 HIT signals. Still further, the multiplexer 340 can include at least one additional block configured to receive a data bit read from one of the first memory cells 112 and a corresponding HIT_q signal. The HIT_q signal can be provided with a first logic state (e.g., logic 1) when none of the 16 HIT signals has a match with the address signal 331, and a second logic state (e.g., logic 0) when one of the 16 HIT signals has a match with the address signal 331.

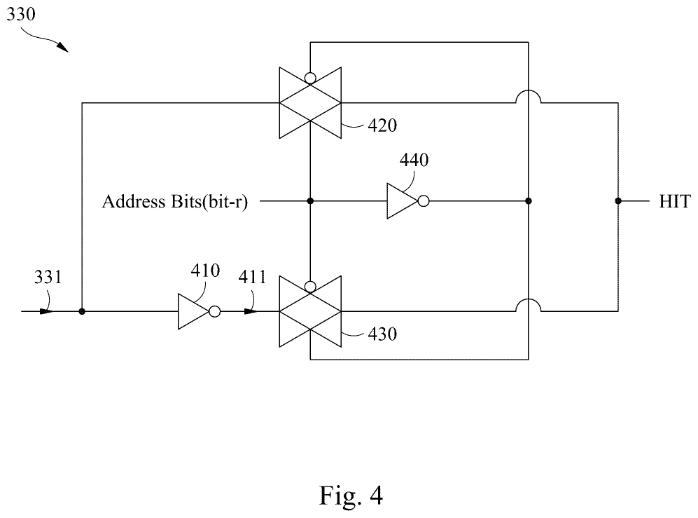

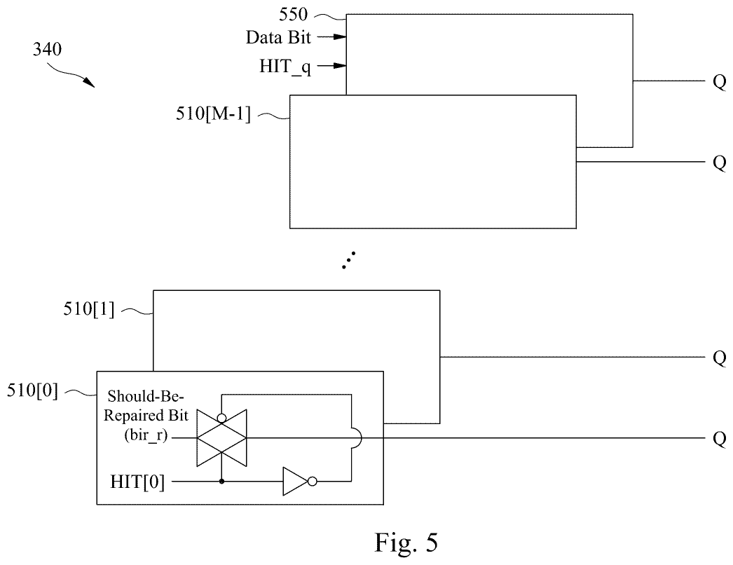

As a result, if there is a match indicated by one of the 16 HIT signals, the multiplexer 340 can select the corresponding should-be-repaired logic 1 or 0, replace the data bit read or otherwise received from the first memory cell 112 with that should-be-repaired bit, and output the should-be-repaired bit as a Q signal; and if there is no match indicated by any of the 16 HIT signals, the multiplexer 340 can select and output the data bit read from the first memory cell 112 as the Q signal. An example circuit diagram of a portion of the compare circuit 330 and an example circuit diagram of the multiplexer 340 will be shown in FIG. 4 and FIG. 5, respectively.

In the example of FIG. 4, the compare circuit 330 can include a first inverter 410, a first transmission gate 420, a second transmission gate 430, and a second inverter 440 formed as a block, in accordance with some embodiments. In the above example where the 256 register circuits are divided into 16 groups configured for repairing 16 of the first memory cells 112, the compare circuit 330 can have 16 of these blocks shown in FIG. 4.

For example, each block is configured to receive the address signal 331, and compare the address signal with the repair address bits (e.g., 14 bits) received from a corresponding one of the register circuits 310[0] to 310[N−1] to output a respective HIT signal. In each of the blocks, specifically, the inverter 410 can receive the address signal 331 and logically invert the address signal 331 as a signal 411. The transmission gate 420 and the transmission gate 430, which are controlled by the address bits received from the register circuits 310 and by repair address bits logically inverted by the inverter 440, are alternately activated to pass along the signal 331 and signal 411, respectively. In general, when the repair address bits match the address signal 331, the HIT signal is provided at logic 1; and when the repair address bits do not match the address signal 331, the HIT signal is provided at logic 0.

In the example of FIG. 5, the multiplexer 340 can include a plural number of blocks 510[0] . . . 510[M−1] where M is equal to 16 in the above example, in accordance with some embodiments. Each block 510 is configured to receive a corresponding of the 16 HIT signal and a corresponding one of the 16 SBR bits. Specifically, each block 510 includes a transmission gate 520 and an inverter 530. The transmission gate 520 can be controlled by the HIT signal and its logically inverted version to be activated, so as to pass along the SBR bit.

For example, if the HIT signal (e.g., HIT[0]) is provided to the block 510[0] as logic 0 (e.g., no match on the address signal 331 and the address bits determined by the compare circuit 330), the multiplexer 340 will not select the SBR bit as its output signal Q. When none of other blocks 510[1] to 510[M−1] selects its received SBR bit, the multiplexer 340 (or block 550) can select the data bit received from the first memory cell 112 as the output signal Q. In some embodiments, the block 550 may be substantially similar to the block 510, e.g., including a transmission gate selectively passing along the data bit based on the above-described HIT_q signal. On the other hand, if the HIT signal (e.g., HIT[0]) is provided as logic 1 (e.g., a match on the address signal 331 and the repair address bits determined by the compare circuit 330), the multiplexer 340 (or block 510[0]) can select the SBR bit forwarded by the corresponding register circuit (e.g., 310[0]) as the output signal Q. As such, the multiplexer 340 may sometimes be referred to as 17-to-1 multiplexer (selecting 1 out of 17 options).

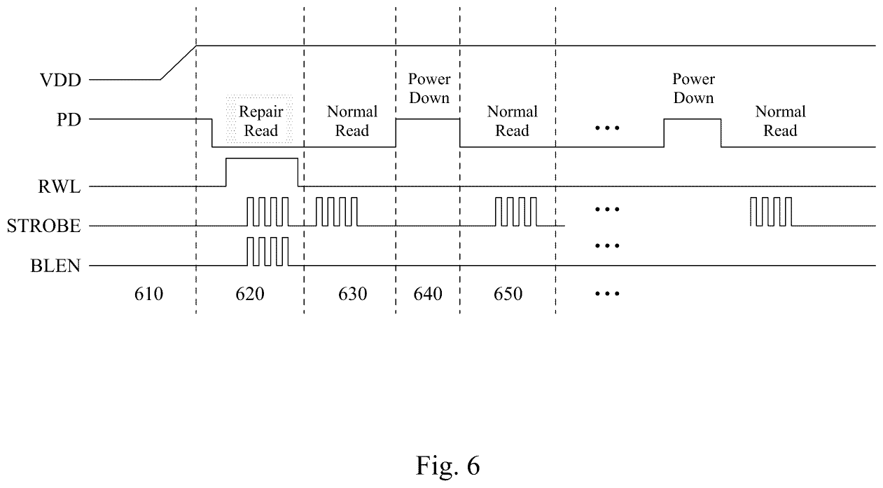

FIG. 6 illustrates waveforms of the control signals, PD, RWL, STROBE, and BLEN, when the memory circuit 100 is configured in different operation modes, in accordance with various embodiments. It should be appreciated that the waveforms of FIG. 6 are merely provided for illustrative purposes. Thus, the waveforms of the PD signal, RWL signal, STROBE signal, and BLEN signal can be arbitrarily scaled while remaining within the scope of the present disclosure.

As shown, the memory circuit 100 can undergo several operation phases (or modes) after being powered up (or provided with a supply voltage). For example, in FIG. 6, the memory circuit 100 can undergo at least operations modes, 610, 620, 630, 640, and 650, where the operation modes 610, 620, 630 and 650, and 640 may sometimes be referred to as a power up mode, a repair read mode, a normal read mode, and a power down mode, respectively. It should be noted that the sequence of the operation modes shown in FIG. 6 is not intended to limit the scope of the present disclosure. Stated another way, the memory circuit 100 can undergo a different combination of the operations modes 620 to 650, while remaining within the scope of the present disclosure.

In the operation mode 610, the memory circuit 100 may transition from no supply voltage provided to a supply voltage (VDD) provided. After the VDD is provided, the power control circuit 150 (of the memory circuit 100) can receive the PD signal transitioning to logic 0, which can enable a header circuit of the power control circuit 150 to provide an operation voltage VDDHD based on the supplied VDD. In some embodiments, the VDDHD can be utilized to drive a number of logic/circuit components of the memory circuit 100, e.g., the sense amplifier 220 and the sense amplifier latch 230 of the I/O circuit 140, the compare circuit 330 and the multiplexer 340 of the repair circuit 160, the controller circuit 170. Further, the power control circuit 150 can provide the column controller 130 with at least another operation voltage, e.g., VDDQ, which can be configured for programming the memory cells of the array 110.

In the operation mode 620, the memory circuit 100 may transition to the repair read mode. In some embodiments, right after the memory circuit 100 is powered up (or provided with a supply voltage), the memory circuit 100 may first transition to the repair read mode before entering into any other operation mode. When in the repair read mode 620, the PD signal may be kept at logic 0, the RWL signal may be pulled up to logic 1, and the STROBE signal may toggle between logic 0 and logic 1. In some embodiments, the STROBE signal may toggle for a certain number of cycles. When the RWL signal is pulled up to logic 1, the BLEN signal can follow the STROBE signal, e.g., when the STROBE signal transitions up, the BLEN signal also transitions up; and when the STROBE signal transitions down, the BLEN signal also transitions down. Further, when the STROBE signal is at logic 1, the sensing components of the I/O circuit 140 (e.g., the sense amplifier 220, the sense amplifier latch 230) can be activated.

Using the circuit diagrams of FIGS. 2-3 as an example, during the repair read mode 620, when the STROBE signal toggles between logic 0 and logic 1, the sense amplifier latch 230 can transition between forwarding and latching the signal 221 (e.g., a repair bit loaded from one of the second memory cells 114) accordingly. For example, when the STROBE signal is at logic 1, the transmission gate 231 is activated and the transmission gate 232 is deactivated, which causes the signal 221 to be forwarded to the repair latch 240 of the register circuit 310 as RIR DATA; and when the STROBE signal is at logic 0, the transmission gate 231 is deactivated and the transmission gate 232 is activated, which causes the signal 221 (or a repair bit previously loaded from the second memory cell 114) to be latched within the sense amplifier latch 230. Upon loading RIR_DATA into the repair latch 240, each of the register circuits 310 can further determine whether to forward or latch the RIR DATA based on the BLEN signal only (as the PD signal is kept at logic 0). For example, when the BLEN signal is at logic 1, the BL_EN signal is provided at logic 1, such that the transmission gate 241 is activated and the transmission gate 242 is deactivated, which causes the RIR_DATA to be forwarded to the compare circuit 330 as its bit_r; and when the BLEN signal is at logic 0, the BL_EN signal is provided at logic 0, such that the transmission gate 241 is deactivated and the transmission gate 242 is activated, which causes the (e.g., previously loaded) RIR_DATA to be latched in the repair latch 240.

In the operation mode 630, the memory circuit 100 may transition to the normal read mode. In some embodiments, right after the repair read mode, the memory circuit 100 can transition to the normal read mode. When in the normal read mode 620, the PD signal may be kept at logic 0, the RWL signal may be pulled down to logic 0, and the STROBE signal may toggle between logic 0 and logic 1. In some embodiments, the STROBE signal may toggle for a certain number of cycles. When the RWL signal is pulled down to logic 0, the BLEN signal may not follow the STROBE signal, e.g., when the STROBE signal transitions up and down, the BLEN signal may stay at logic 0. As such, the RIR_DATA is latched within the repair latch of each of the register circuits 310, and the multiplexer 340 can read the data bit stored in the first memory cell 112 after determining no match between the address signal 331 and the repair address bits.

In the operation mode 640, the memory circuit 100 may transition to the power down mode. In some embodiments, after a number of cycles of performing the normal read modes, the memory circuit 100 can transition to the power down mode. When in the power down mode 640, the PD signal may be pulled up to logic 1. Upon the PD signal transitioning to logic 1, each of the register circuits 310 is configured to latch its RIR_DATA inside the corresponding repair latch 240. For example, in FIG. 3, when the PD signal is at logic 1, the BL_EN signal is provided at logic 0, such that the transmission gate 241 is deactivated and the transmission gate 242 is activated, which causes the (e.g., previously loaded) RIR_DATA to be latched in the repair latch 240. Further, as described above, each of the components of the register circuit 310 is powered by the supply voltage VDD, and thus, even if the memory circuit 100 entering into the power down mode (e.g., VDDHD being removed), the register circuit 310 can still latch, hold, or otherwise keep the previously loaded RIR_DATA. Accordingly, after the power down mode (e.g., 640), the memory circuit 100 is not required to switch into another repair read mode and can be directly configured in a normal read mode (e.g., 650).

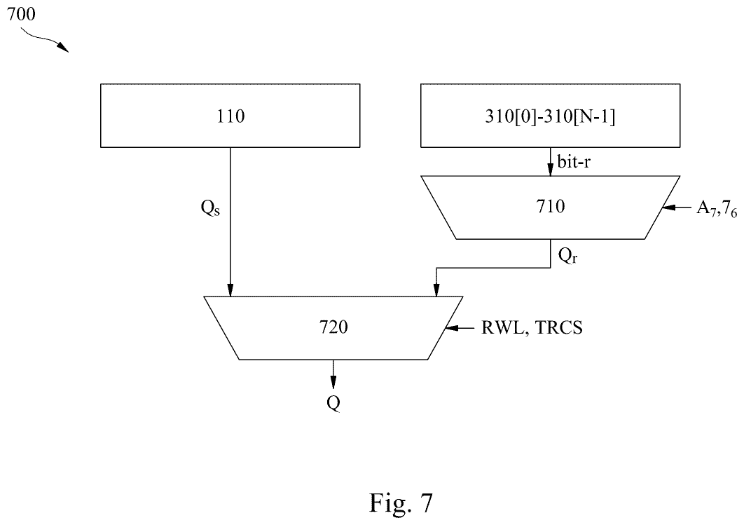

FIG. 7 illustrates a schematic diagram of another implementation of the memory circuit 100, in accordance with some embodiments. As a brief overview, the memory circuit 100 shown in FIG. 7 (hereinafter “memory circuit 700”) can have a number of multiplexers to verify the repair signal stored in the register circuits 310 (e.g., bit_r bits). It should be noted that the schematic diagram of FIG. 7 is merely provided as an illustrative example, and thus, the schematic diagram of FIG. 7 can include any of various other components while remaining within the scope of the present disclosure.

As shown, in addition to the memory array 110 and the register circuits 310[0] to 310[N−1], the memory circuit 700 can include a first multiplexer 710 and a second multiplexer 720. The multiplexer 710, controlled by control signals A6 and A7, is configured to receive the repair signal (e.g., bit_r bits) from the register circuits 310[0] to 310[N−1]. In the above example where N=256 (256 register circuits), the multiplexer 710 can receive 256 of the bit_r bits, bit_r<0:255>. In some embodiments, depending on different combinations of logic states of the A6 and A7 signals, the multiplexer 710 can select or output respective portions of those 256 bit_r bits as Qr. For example, when the A6 and A7 signal are both at logic 0, the multiplexer 710 outputs bit_r<0:63> as Qr<0:63>; when the A6 and A7 signal are at logic 0 and logic 1, respectively, the multiplexer 710 outputs bit_r<64:127> as Qr<0:63>; when the A6 and A7 signal are at logic land logic 0, respectively, the multiplexer 710 outputs bit_r<128:191> as Qr<0:63>; and when the A6 and A7 signal are both at logic 1, the multiplexer 710 outputs bit_r<192:255> as Qr<0:63>. As such, the multiplexer 710 may be sometimes referred to as a 4-to-1 multiplexer.

The multiplexer 720, controlled by control signals RWL and TRCS, is configured to receive data bits, Qs, from the memory array 110. For example, the multiplexer 720 may receive 64 of the data bits, Qs<0:63>, and the output of the multiplexer 710, Qr<0:63>. In some embodiments, depending on different combinations of logic states of the RWL and TRCS signals, the multiplexer 720 can select Qs or Qr as its output, Q. For example, when the RWL signal and the TRCS signal are both at logic 1, the multiplexer 720 outputs the Qr as the Q (i.e., selecting the repair bits from the register circuits 310 as its output). The memory circuit may be referred to as be configured in a register read mode, when the multiplexer 720 selects the repair bits from the register circuits as its output. Otherwise, the multiplexer 720 outputs the Qs as the Q (i.e., not selecting the repair bits from the register circuits 310 as its output).

Table below summarizes combinations of logic states of several control signals when configuring the memory circuit 100 in different operation modes, respectively. For example, CSB signal, STROBE signal, PD signal, RWL signal, and TRCS signal are shown. In some embodiments, these control signals may be received by the power control circuit 150, the repair circuit 160, and/or the controller circuit 170. When configuring the memory circuit 100 in the repair read mode, the CSB, STROBE, PD, RWL, and TRCS signals may be provided at logic 0, as toggling between logic 0 and 1, at logic 0, at logic 1, and at logic 0, respectively. When configuring the memory circuit 100 in the normal read mode, the CSB, STROBE, PD, RWL, and TRCS signals may be provided at logic 0, as toggling between logic 0 and 1, at logic 0, at logic 0, and at logic 0, respectively. When configuring the memory circuit 100 in the power down mode, the CSB, STROBE, PD, RWL, and TRCS signals may be provided at logic 1, as “don't care,” at logic 1, as “don't care,” and as “don't care,” respectively. When configuring the memory circuit 100 in the register read mode, the CSB, STROBE, PD, RWL, and TRCS signals may be provided at logic 0, as toggling between logic 0 and 1, at logic 0, at logic 0, and at logic 1, respectively.

TABLE

| Mode | CSB | STROBE | PD | RWL | TRCS |
|---|---|---|---|---|---|
| Repair Read | 0 | 0/1 | 0 | 1 | 0 |
| Normal Read | 0 | 0/1 | 0 | 0 | 0 |
| Power Down | 1 | X | 1 | X | X |
| Register Read | 0 | 0/1 | 0 | 0 | 1 |

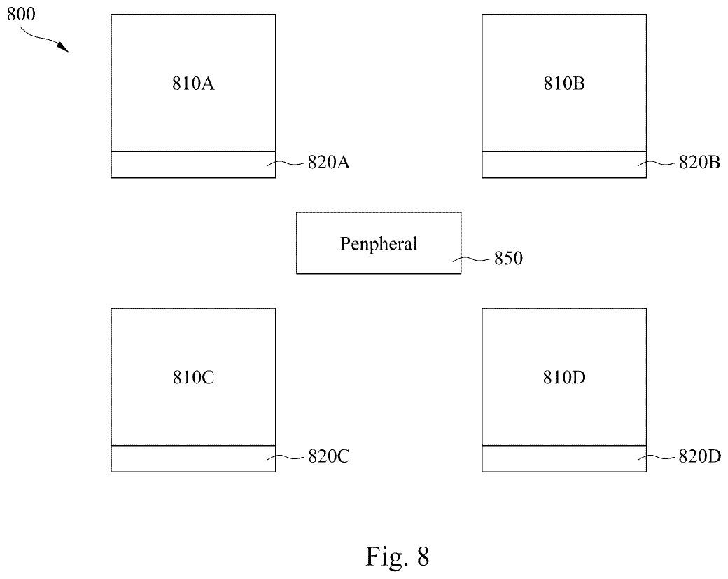

FIG. 8 illustrates an example layout 800 of a memory circuit that can include the memory circuit 100, in accordance with various embodiments. As shown, the layout 800 includes four memory arrays 810A, 810B, 810C, and 810D, wherein each of the memory arrays 810A to 810D is substantially similar to the memory array 110. For example, each of the memory arrays 810A to 810D includes at least two types of memory cells, one of which is configured to store a data bit (sometimes referred to as main memory cells), and the other of which is configured to store repair bit (sometimes referred to as redundant memory cells). Further, each of the memory arrays 810A to 810D can include a redundant row or column (e.g., 820A, 820B, 820C, 820D), in which the redundant memory cells can be disposed. In some embodiments, the four memory arrays 810A to 810D may be arranged with respect to a peripheral circuit block 850 of the layout 800, which can include a controller circuit (e.g., 170), a power control circuit (e.g., 150), a repair circuit (e.g., 160), etc. The four memory arrays 810A to 810D can share the circuit components formed in the peripheral circuit block 850.

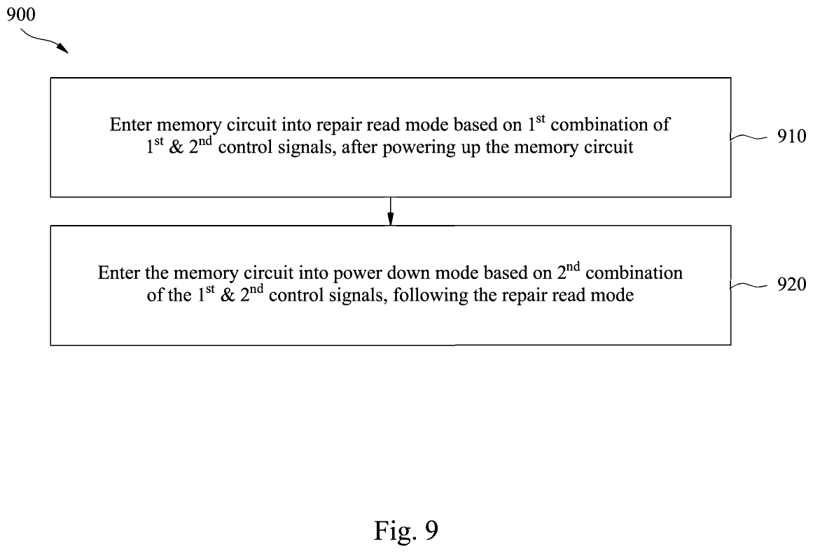

FIG. 9 illustrates a flow chart of an example method 900 for operating a memory circuit that includes or is operatively coupled with a repair circuit, in accordance with various embodiments. For example, at least some of the operations (or steps) of the method 900 can be used to operate the memory circuit 100 (FIG. 1). It is noted that the method 900 is merely an example, and is not intended to limit the present disclosure. Accordingly, it should be understood that additional operations may be provided before, during, and/or after the method 900 of FIG. 9, and that some other operations may only be briefly described herein.

The method 900 starts with operation 910 of entering a memory circuit into a repair read mode based on a first combination of logic states of a first control signal and a second control signal, after powering up the memory circuit. Further, in some embodiments, the repair read mode can include transferring a current repair bit to a register circuit and latching a previous repair bit in the register circuit. Using the circuit diagram of FIG. 3 as a representative example, when configuring the memory circuit in the repair read mode, the PD signal may be provided at logic 0, while the BLEN signal may be logically combined as toggling between logic 0 and logic 1. When the PD signal at logic 0 and the BLEN signal at logic 0, the previously loaded repair bit (e.g., RIR_DATA) may be latched within the repair circuit 310 (or the repair latch 240); and when the PD signal at logic 0 and the BLEN signal at logic 1, the currently loaded repair bit (e.g., RIR_DATA) may be forwarded by the repair circuit 310 to the next stage of circuit (e.g., the compare circuit 330).

The method 900 continues to operation 920 of entering the memory circuit into a power down mode based on a second combination of the logic states of the first control signal and the second control signal, following the repair read mode. Further, in some embodiments, the power down mode can include latching the repair bit in the register circuit. When configuring the memory circuit in the power down mode, the PD signal may be provided at logic 1. Continuing with the above example, when configuring the memory circuit in the power down mode, the PD signal may be provided at logic 1, such that the repair latch 240 of the repair circuit 310 is configured to latch the previously loaded repair bit (e.g., RIR_DATA). In some embodiments, the repair read mode is configured to occur prior to the power down mode, and since during the power down mode, the repair bit is latched within the register circuit (i.e., kept in the register circuit even entering into the power down mode), the memory circuit can directly transition to a normal read mode (i.e., no need to perform another repair read mode).

In one aspect of the present disclosure, a memory circuit is disclosed. The memory circuit includes a memory array comprising a plurality of first memory cells and a plurality of second memory cells, each of the plurality of first memory cells configured to store a data bit and each of the plurality of second memory cells configured to store a repair bit; a plurality of register circuits; and a compare circuit coupled to the plurality of register circuits. Each of the plurality of register circuits is configured to receive the repair bit from a corresponding one of the plurality of second memory cells; transfer the received repair bit to the compare circuit when the memory circuit is configured in a first operation mode; and latch the received repair bit in the register circuit when the memory circuit is configured in a second operation mode.

In another aspect of the present disclosure, a memory circuit is disclosed. The memory circuit includes a memory array comprising a plurality of first memory cells and a plurality of second memory cells, each of the plurality of first memory cells configured to store a data bit and each of the plurality of second memory cells configured to store a repair bit; and a plurality of register circuits. Each of the plurality of register circuits is configured to receive the repair bit from a corresponding one of the plurality of second memory cells; and latch the received repair bit in the register circuit when the memory circuit is configured in a power down mode through at least a first control signal.

In yet another aspect of the present disclosure, a method for operating a memory circuit is disclosed. The method includes entering a memory circuit into a repair read mode based on a first combination of logic states of a first control signal and a second control signal, after powering up the memory circuit, wherein the repair read mode comprises transferring a repair bit to a register circuit. The method includes entering the memory circuit into a power down mode based on a second combination of the logic states of the first control signal and the second control signal, following the repair read mode, wherein the power down mode comprises latching the repair bit in the register circuit.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory array comprising a plurality of first memory cells and a plurality of second memory cells, each of the plurality of first memory cells configured to store a data bit and each of the plurality of second memory cells configured to store a repair bit;
a plurality of register circuits; and
a compare circuit coupled to the plurality of register circuits;
wherein each of the plurality of register circuits is configured to:
receive the repair bit from a corresponding one of the plurality of second memory cells;
transfer the received repair bit to the compare circuit when the memory circuit is configured in a first operation mode; and
latch the received repair bit in the register circuit when the memory circuit is configured in a second operation mode.

2. The memory circuit of claim 1, wherein a plural number of the repair bits are collectively associated with a corresponding one of the plurality of first memory cells, and wherein the plural number of the repair bits indicate a location of the corresponding first memory cell in the memory array, whether the plural number of the repair bits are still capable of repairing, and whether the corresponding first memory cell is to be repaired as logic 0 or logic 1.

3. The memory circuit of claim 1, wherein each of the plurality of register circuits comprises at least:
a NAND gate;
a first transmission gate;
a second transmission gate;
a first inverter; and
a second inverter.

4. The memory circuit of claim 3, wherein the NAND gate is configured to receive a first signal and a second signal, and wherein the first signal is provided at a first logic state in the second operation mode, and at a second logic state in the first operation mode.

5. The memory circuit of claim 4, wherein the first signal, when provided at the first logic state, corresponds to the second operation mode, regardless of a logic state of the second signal.

6. The memory circuit of claim 4, wherein the second signal, when provided at the first logic state, corresponds to the second operation mode, with the first signal provided at the second logic state, and wherein the second signal, when provided at the second logic state, corresponds to the first operation mode, with the first signal provided at the second logic state.

7. The memory circuit of claim 3, wherein, in the first operation mode, the first transmission gate is activated to pass a currently received repair bit to the compare circuit.

8. The memory circuit of claim 7, wherein, in the second operation mode, the first transmission gate is deactivated, which causes a previously received repair bit to be latched within the second transmission gate, the first inverter, and the second inverter.

9. The memory circuit of claim 1, further comprising a multiplexer configured to:
receive the stored data bit and the repair bits from the memory array and the compare circuit, respectively;
select one or more of the repair bits as a first output signal when the memory circuit is configured in the first operation mode.

10. The memory circuit of claim 9, wherein, when the memory circuit is configured in the first operation mode, the compare circuit is configured to:
receive an address signal indicating a location of a corresponding one of the plurality of first memory cells in the memory array;
compare the address signal with one or more of the repair bits transferred by the respective register circuits; and
provide a second output signal in response to a match between the address signal and the one or more repair bits.

11. The memory circuit of claim 10, further comprising a sense amplifier circuit operatively coupled between the memory array and the plurality of register circuits.

12. A memory circuit, comprising:
a memory array comprising a plurality of first memory cells and a plurality of second memory cells, each of the plurality of first memory cells configured to store a data bit and each of the plurality of second memory cells configured to store a repair bit; and
a plurality of register circuits;
wherein each of the plurality of register circuits is configured to:
receive the repair bit from a corresponding one of the plurality of second memory cells; and
latch the received repair bit in the register circuit when the memory circuit is configured in a power down mode through at least a first control signal.

13. The memory circuit of claim 12, wherein each of the plurality of register circuits is configured to transfer the received repair bit to a later stage circuit when the memory circuit is configured in a repair read mode through at least the first control signal and a second control signal.

14. The memory circuit of claim 13, wherein the repair read mode is configured to occur prior to the power down mode.

15. The memory circuit of claim 13, wherein the first control signal is provided at a first logic state when the memory circuit is configured in the power down mode, and the first control signal and the second control signal are provided at a second logic state and the first logic state, respectively, when the memory circuit is configured in the repair read mode.

16. The memory circuit of claim 12, wherein each of the plurality of register circuits comprises at least:
a NAND gate;
a first transmission gate;
a second transmission gate;
a first inverter; and
a second inverter.

17. The memory circuit of claim 12, wherein a plural number of the repair bits are collectively associated with a corresponding one of the plurality of first memory cells, and wherein the plural number of the repair bits indicate a location of the corresponding first memory cell in the memory array, whether the plural number of the repair bits are still capable of repairing, and whether the corresponding first memory cell is to be repaired as logic 0 or logic 1.

18. A method for operating a memory circuit, comprising:
entering a memory circuit into a repair read mode based on a first combination of logic states of a first control signal and a second control signal, after powering up the memory circuit, wherein the repair read mode comprises transferring a repair bit to a register circuit; and
entering the memory circuit into a power down mode based on a second combination of the logic states of the first control signal and the second control signal, following the repair read mode, wherein the power down mode comprises latching the repair bit in the register circuit.

19. The method of claim 18, further comprising entering the memory circuit into a normal read mode right after the power down mode.

20. The method of claim 18, wherein the register circuit comprises at least:
a NAND gate;
a first transmission gate;
a second transmission gate;
a first inverter; and
a second inverter.
